(19) United States
(12) Patent Application Publication
(10) Pub. No.: US 2026/0096010 A1
(43) Pub. Date: Apr. 2, 2026

(54) GRAPHICS PROCESSING SUBSYSTEMS WITH DUAL BLOW-THROUGH ARCHITECTURES

(71) Applicant: NVIDIA Corporation, Santa Clara, CA (US)

(72) Inventors: Xiangyang AN, Shenzhen (CN); Siarhei MURAUYOU, Los Gatos, CA (US); Yunseok KIM, Pleasanton, CA (US); Rikun JI, Fremont, CA (US); Andrew BELL, San Francisco, CA (US); Boris LANDWEHR, Los Gatos, CA (US); Gabriele GORLA, Santa Clara, CA (US); Jaekyu JUNG, Los Gatos, CA (US); Jungho NA, Milpitas, CA (US); Malcolm GUTENBURG, San Francsico, CA (US); Xiang SUN, Los Gatos, CA (US); Mykola GROMOV, Sunnyvale, CA (US); Sien CHEN, Shenzhen, Guangdong (CN); Zhenguang HUANG, Shenzhen (CN); Xuan WANG, Shenzhen (CN); Xin YANG, Shenzhen (CN); Xiang ZHU, Shenzhen (CN)

(73) Assignee: NVIDIA Corporation, Santa Clara, CA (US)

(21) Appl. No.: 18/923,648

(22) Filed: Oct. 22, 2024

(30) Foreign Application Priority Data
Sep. 29, 2024 (WO) PCT/CN2024/122424

(51) Int. Cl. H05K 1/02

(52) U.S. Cl. CPC H05K 1/0203; H05K 2201/064; H05K 2201/066

(57) ABSTRACT

Example graphics processing subsystems and computing devices that include the graphics processing subsystem(s) are described. In one example, the graphics processing subsystem may comprise a first fan, a second fan and a printed circuit board (PCB) on which a processor is disposed. The first fan may be associated with a first axis about which the first fan is rotatable. The second fan may be associated with a second axis about which the second fan is rotatable. The PCB may be shaped and positioned such that (a) a first airflow path for cooling the processor traverses through the first fan and a first opening below the first fan, and (b) a second airflow path for cooling the processor traverses through the second fan and a second opening below the second fan. The first airflow path and the second airflow path are substantially linear relative to the respective first axis and second axis.

### CROSS-REFERENCE TO RELATED APPLICATION

The present application claims the benefit of Patent Cooperation Treaty (PCT) Application No. PCT/CN2024/122424, filed Sep. 29, 2024, which is incorporated herein by reference.

### BACKGROUND

A conventional graphics processing subsystem usually includes a printed circuit board (PCB)—upon which a graphics processing unit (GPU) is disposed, at least one fan, and a heat sink. The GPU is normally integrated into the PCB while electronically coupled to various other electronic components. The heat sink is thermally coupled to the GPU and/or the PCB, and may include a set of cooling fins. The fan is typically disposed proximate to the heat sink and may be configured to direct airflow toward the cooling fins.

In practice, GPUs are specialized hardware accelerators for improving the performance of graphics-intensive applications, such as the creation and rendering of images, animations, and videos, etc. Compared to a conventional central processing unit (CPU), a GPU is usually optimized for parallel processing, which makes it more efficient at handling complex computations that are performed multiple times in concert. Beyond graphics, GPUs have become important in fields like artificial intelligence (AI) and physics simulations, where high-speed data processing is required. During operation, GPUs may generate a significant amount of heat that needs to be dissipated in order to prevent overheating. As such, effective heat management for GPUs is desirable to, inter alia, improve performance and reduce the likelihood of thermal damage.

### BRIEF DESCRIPTION OF DRAWINGS

FIG. 1 is a schematic diagram illustrating a side view of a first example graphics processing subsystem according to embodiments of the present disclosure;

FIG. 2A is a schematic diagram illustrating a top view of the first example graphics processing subsystem in FIG. 1;

FIG. 2B is a schematic diagram illustrating a perspective view of the first example graphics processing subsystem in FIG. 1;

FIG. 3A is a schematic diagram illustrating a top view of the first example graphics processing subsystem in FIG. 1 when its fans are removed;

FIG. 3B is a schematic diagram illustrating a perspective view of the first example graphics processing subsystem in FIG. 1 when its fans are removed;

FIG. 4A is a schematic diagram illustrating a top view of an example printed circuit board (PCB) in the first example graphics processing subsystem in FIG. 1;

FIG. 4B is a schematic diagram illustrating a perspective view of an example PCB in the first example graphics processing subsystem in FIG. 1;

FIG. 5 is a schematic diagram illustrating a side view a second example graphics processing subsystem according to embodiments of the present disclosure;

FIG. 6A is a schematic diagram illustrating a top view of a first example PCB in a graphics processing subsystem;

FIG. 6B is a schematic diagram illustrating a top view of a second example PCB that is shaped to include curved-in edges;

FIG. 7A is a schematic diagram illustrating a top view of a third example PCB that is shaped to include cut-outs;

FIG. 7B is a schematic diagram illustrating a side view of a third example graphics processing subsystem that includes a PCB shaped with cut-outs;

FIG. 8 is a schematic diagram illustrating a side view of a fourth example graphics processing subsystem that includes a PCB shaped with cut-outs;

FIG. 9A is a schematic diagram illustrating a fifth example graphics processing subsystem that includes three fans;

FIG. 9B is a schematic diagram illustrating a sixth example graphics processing subsystem that includes four fans;

FIG. 10 is a schematic diagram illustrating an example computer system that includes a graphics processing subsystem according to embodiments of the present disclosure.

### SUMMARY

According to embodiments of the present disclosure, there is provided a graphics processing subsystem comprising a first fan, a second fan, and a printed circuit board (PCB) on which a processor (e.g., a graphics processing unit (GPU)) resides. The first fan may be associated with a first axis about which the first fan is rotatable. The second fan may be associated with a second axis about which the second fan is rotatable. The PCB may be shaped and positioned such that (a) a first airflow path for cooling the processor traverses through the first fan and a first opening below the first fan, and (b) a second airflow path for cooling the processor traverses through the second fan and a second opening below the second fan. The first airflow path and the second airflow path may be substantially linear relative to the respective first axis and second axis.

Using embodiments of the present disclosure, a graphics processing subsystem may be configured to implement a dual blow-through architecture such that both the first fan and the second fan are capable of operating as blow-through fans (to be discussed further below). In practice, embodiments of the present disclosure may be implemented to improve heat dissipation in graphics processing subsystems. For example, by improving heat dissipation, the overall performance and stability of a graphics processing subsystem may be enhanced. This may in turn reduce the likelihood of thermal throttling, which occurs when the processor reduces its speed to avoid overheating. This way, the graphics processing subsystem may maintain relatively high performance levels, even when performing tasks that require high computational power.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the drawings, can be arranged, substituted, combined, and designed in a wide variety of different configurations, all of which are explicitly contemplated herein.

Although the terms “first” and “second” are used to describe various elements, these elements should not be limited by these terms. These terms are used to distinguish one element from another. For example, a first element may be referred to as a second element, and vice versa. The phrase “at least one of” does not require selection of at least one of each item listed; rather, the phrase allows a meaning that includes at least one of any one of the items, and/or at least one of any combination of the items. By way of example, the phrases “at least one of A, B, and C” or “at least one of A, B, or C” each refer to only A, only B, or only C; and/or any combination of A, B, and C. In instances where it is intended that a selection be of “at least one of each of A, B, and C,” or alternatively, “at least one of A, at least one of B, and at least one of C,” it is expressly described as such.

As the power of graphics processing units (GPUs) increases, an improved cooling mechanism is desirable to dissipate heat generated by the GPUs into ambient air. In practice, one significant thermal resistance in air-cooled discrete graphics cards is the airflow thermal resistance, meaning that increasing airflow generally has the greatest impact on thermal performance and the overall performance of the graphics cards. To increase airflow, it is desirable to reduce the pressure drop of a graphics processing subsystem. Here, the “pressure drop” may refer generally to the reduction in air pressure as air moves through the graphics processing subsystem. A higher pressure drop means more resistance, which may reduce the overall airflow and lead to less effective cooling. By comparison, higher airflow with minimal pressure drop achieves more efficient heat dissipation. Conventionally, one approach to reduce pressure drop is to increase the space between heat sink fins (i.e., fin spacing). However, such conventional approach necessitates the removal of effective fins, which in turn reduces the overall cooling.

According to embodiments of the present disclosure, a “blow through” architecture may be implemented to enhance the cooling performance of graphics processing subsystems. As used herein, the term “blow-through” may refer generally to an architecture that allows a fan to blow air directly through a graphics processing subsystem with minor or no redirection. A fan capable of implementing the blow-through architecture may be known as a “blow-through fan. ” In particular, according to embodiments of the present disclosure, a multiple (N) blow-through architecture may be implemented for an N number of fans. As will be described below using at least N=2 fans, a graphics processing subsystem with a dual blow-through architecture may include at least two blow-through fans.

Embodiments of the present disclosure should be contrasted against conventional approaches that only include one (or no) blow-through fan. One example is described in related U.S. Pat. No. 11,681,340 B2 entitled “Blow-through axial fan for a graphics processing unit,” which in incorporated herein by reference. In this example, only one out of two fans may operate as a blow-through fan. An airflow path of at least one fan curves at least ninety degrees when impeded and redirected by a PCB, resulting in less efficient cooling.

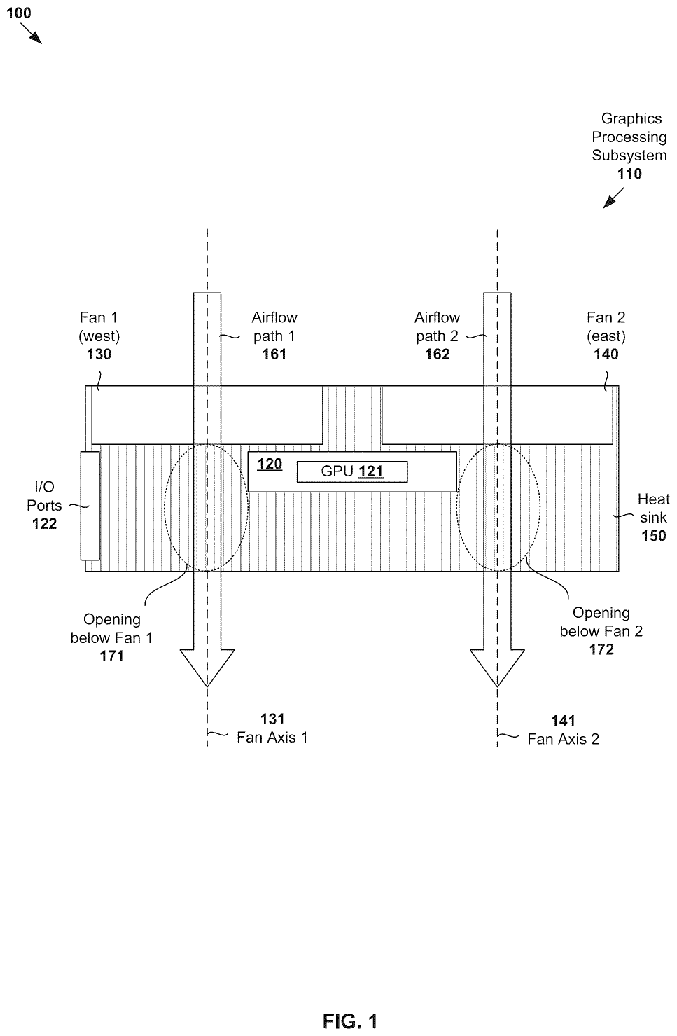

In contrast, according to embodiments of the present disclosure, a PCB of a graphics processing subsystem may be shaped and positioned to facilitate a dual blow-through architecture. By improving the cooling mechanism according to embodiments of the present disclosure, the graphics processing subsystem may be equipped with higher-performance GPU(s) relative to GPU(s) in conventional graphics processing subsystems. In practice, higher-performance GPUs generally operate at a higher frequency and clock speed. However, higher-frequency GPUs usually generate more heat than GPUs that operate at lower frequencies. In the following, various embodiments will be discussed using FIGS. 1-10.

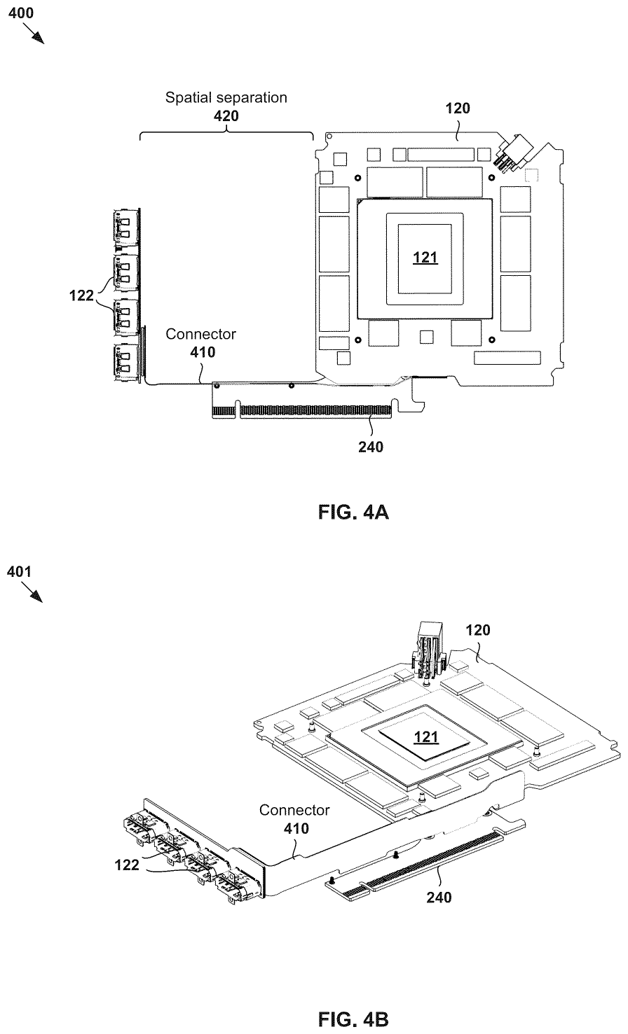

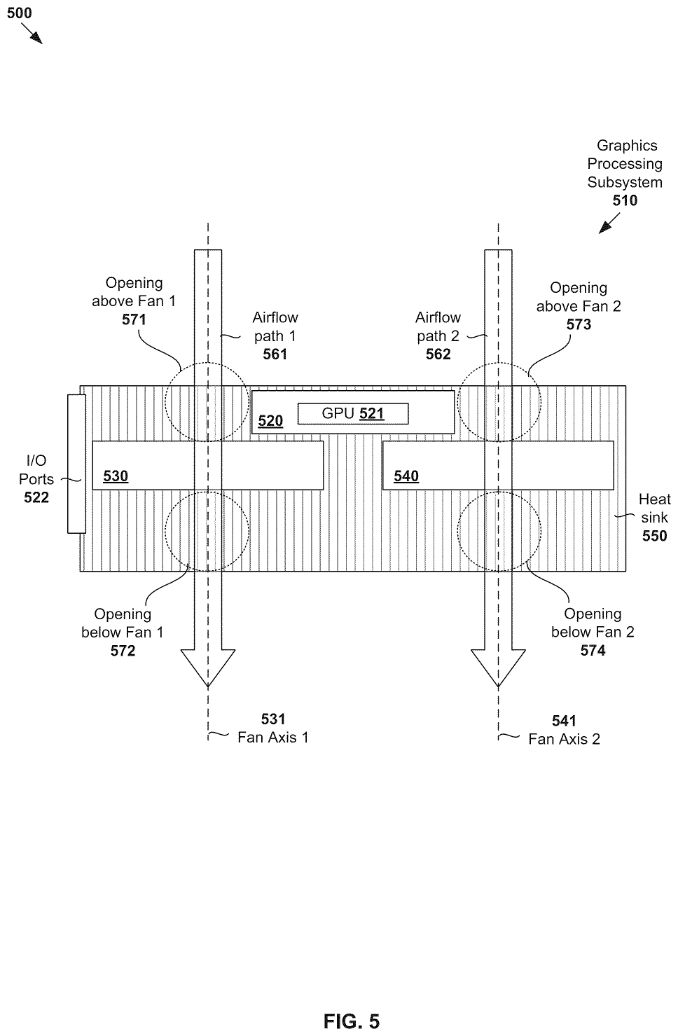

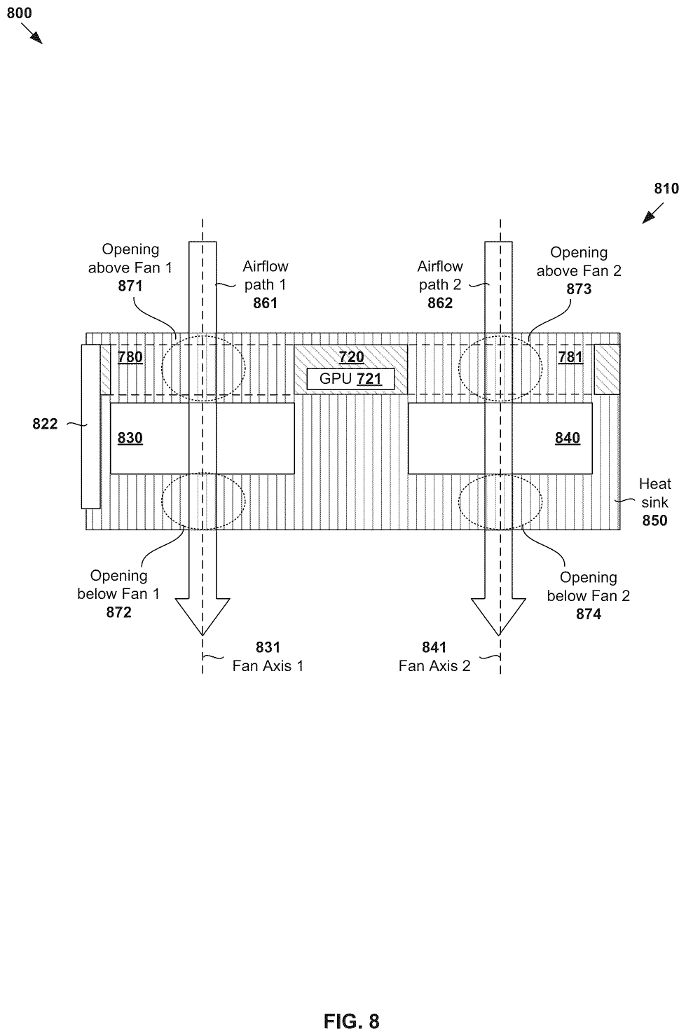

In relation to positioning, the PCB may be positioned at a distance from multiple input/output (I/O) ports of the graphics processing subsystem (e.g., see FIGS. 1, 4A-B and 6A-B). In some embodiments, the PCB may be positioned substantially below a first fan and a second fan (e.g., see FIGS. 1, 7B, 9A-B). In other embodiments, the PCB may be positioned substantially above the first fan and the second fan (e.g., FIGS. 5 and 8). In further embodiments, the PCB may be positioned between a first axis associated with the first fan and a second axis associated with the second fan in a middle section of the graphics processing subsystem (see FIGS. 1-5).

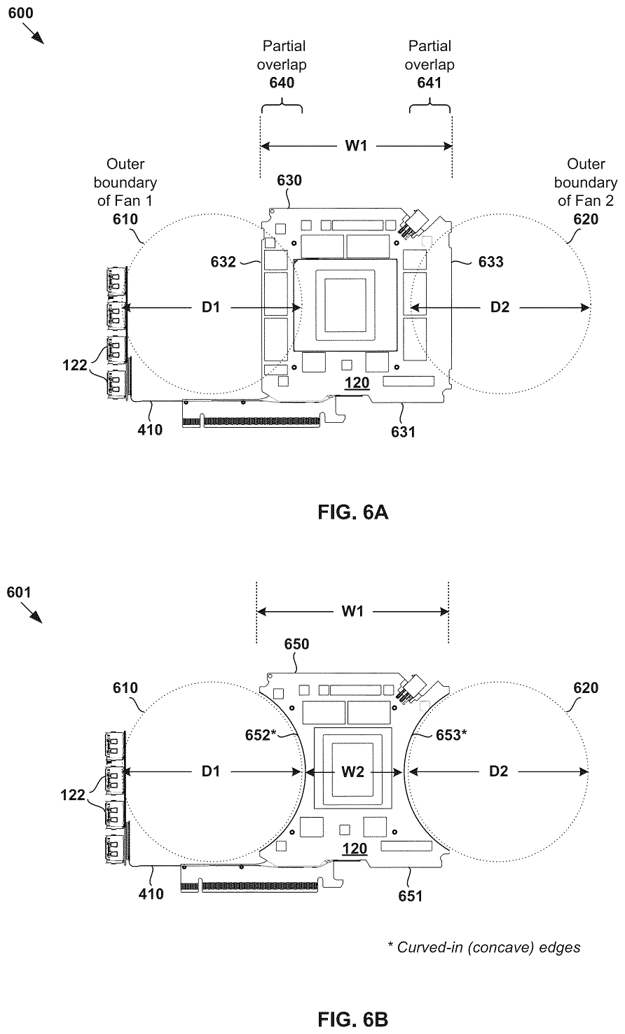

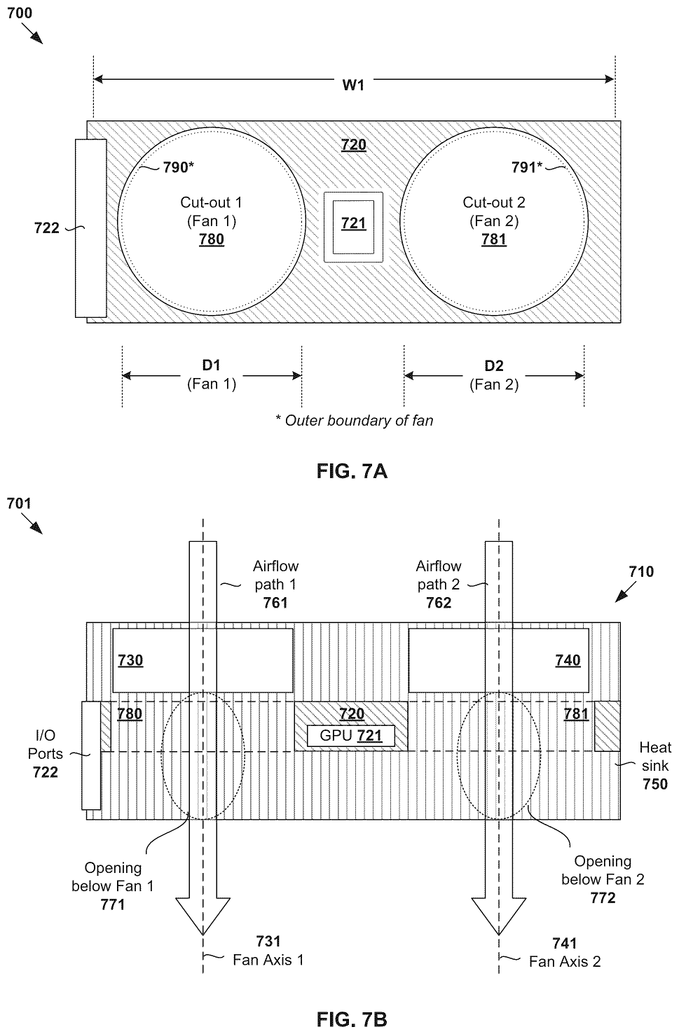

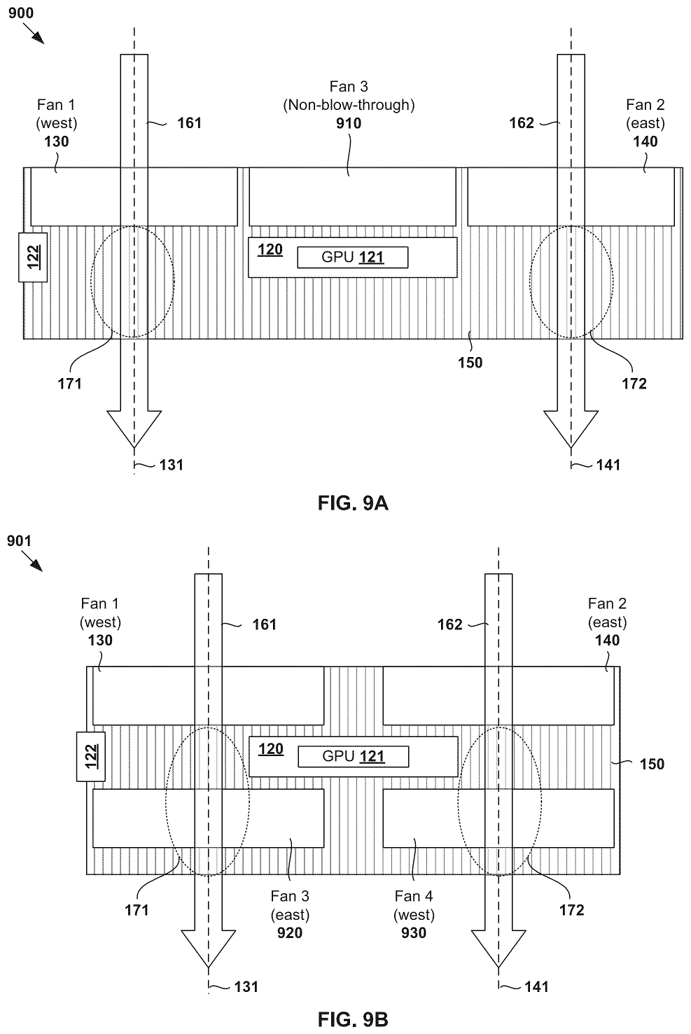

In relation to shape configurations, the PCB may have any suitable shape. In one example, the PCB may be configured to have a generally rectangular or square shape (e.g., see FIGS. 4A-B and 6A). In another example, the PCB may be shaped to include curved-in edges (e.g., see FIG. 6B). In a further example, the PCB may be shaped to include cut-outs (e.g., see FIGS. 7A-B and 8). Depending on the desired implementation, additional fan(s) may be included (e.g., see FIGS. 9A-B). Any suitable size of the PCB may be configured to facilitate the dual blow-through architecture.

### Example Graphics Processing Subsystem

As used herein, the term “graphics processing subsystem” may refer generally to a collection of components that are configured to support graphics and/or compute-intensive processing. A graphics processing subsystem may be one part of a computer system or computing node within a larger ecosystem of computing resources (e.g., a data center). The term “graphics processing unit” or “GPU” may refer generally to a processor that is capable of performing graphics processing, as well as other compute-intensive processing beyond graphics. For example, a GPU may have a parallel processing architecture that is designed for handling multiple tasks simultaneously. Beyond graphics, GPUs may be used to accelerate high-performance computing, deep learning and artificial intelligence, and other engineering applications. The term “printed circuit board” or “PCB” may refer generally to a board to electrically connect electronic components.

A first example will be explained using FIGS. 1-4B. Here, FIG. 1 is a schematic diagram illustrating a side view 100 of a first example graphics processing subsystem 110 according to embodiments of the present disclosure. Here, graphics processing subsystem 110 may include PCB 120 on which processor 121 is disposed, heat sink 150, and a set of axial fans 130-140 that are positioned above PCB 120 and heat sink 150. PCB 120 may also include additional components (not shown for simplicity) to support any suitable application(s).

According to embodiments of the present disclosure, PCB 120 may be shaped and positioned such that airflow paths 161-162 are substantially linear relative to respective axes 131, 141. First fan 130 (known as a west fan) may be an axial fan that is associated with first axis 131 about which first fan 130 is rotatable. Second fan 140 (known as an east fan) may be an axial fan that is associated with second axis 141 about which second fan 140 is rotatable. First axis 131 and second axis 141 may be substantially perpendicular relative to PCB 120. The term “substantially perpendicular” may include true perpendicular, or additionally with minor deviation(s) therefrom.

During operation, air may be directed along both first airflow path 161 and second airflow path 162 before being dispelled to dissipate heat generated by GPU 121. First airflow path 161 for cooling GPU 121 may traverse through first fan 130, first opening 171 below first fan 130, and heat sink 150. This is to achieve a first blow-through effect, in that first airflow path 161 is substantially linear relative to first axis 131 associated with first fan 130. Similarly, second airflow path 162 for cooling GPU 121 may traverse through second fan 140, second opening 172 below second fan 140, and heat sink 150. This is to achieve a second blow-through effect, in that second airflow path 162 is substantially linear relative to second axis 141.

To accommodate blow-through fans 130-140 in the example in FIG. 1, PCB 120 may be positioned in a middle section of graphics processing subsystem 110 between first axis 131 and second axis 141. This middle positioning helps to ensure that airflow paths 161-162 traverse outside of a boundary (e.g., first and second edges) of PCB 120, i.e., with little or no redirection by PCB 120. Since airflow path 161/162 is substantially linear relative to axis 131/132, pressure drop may be reduced to achieve increased airflow and greater heat dissipation. As used herein, the term “substantially linear relative to an axis” may refer to an airflow path that is generally straight compared to the axis, within an acceptable range of minor deviations (e.g., curves less than a threshold amount).

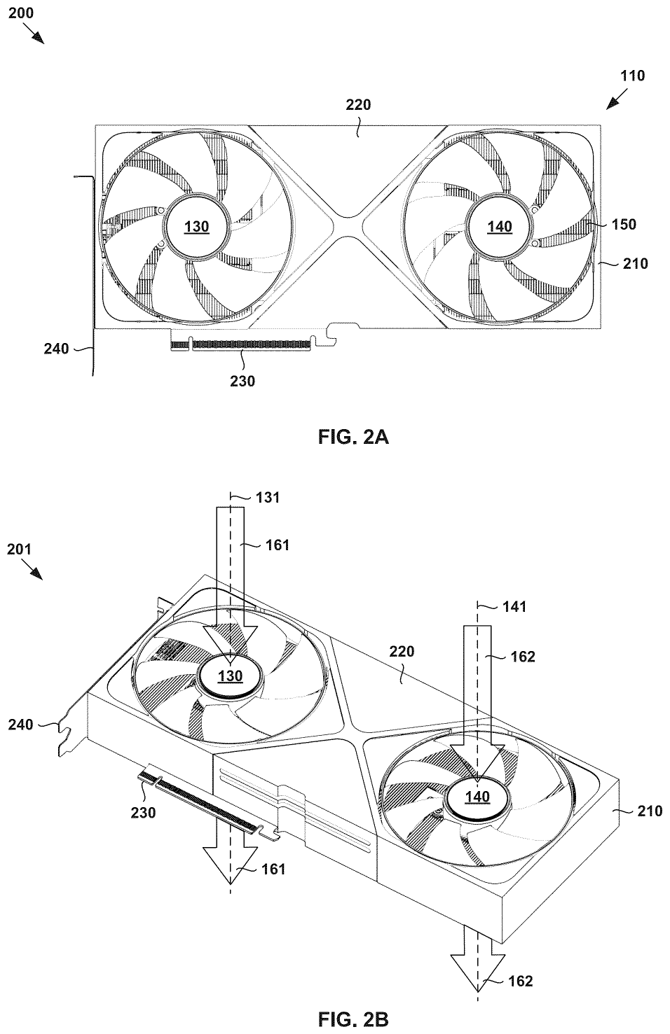

FIG. 2A is a schematic diagram illustrating a top view 200 of a first example graphics processing subsystem 110 in FIG. 1, and FIG. 2B is a schematic diagram illustrating a perspective view 201 of a first example graphics processing subsystem 110 in FIG. 1. As shown in FIGS. 2A-B, graphics processing subsystem 110 may further include main body/frame 210, top cover 220 that is attachable to main body 210, Peripheral Component Interconnect Express (PCIe) connector 230, and Input/Output (I/O) port bracket 240. Top cover 220 may include cut-outs to accommodate respective axial fans 130-140, which are positioned substantially above PCB 120 and heat sink 150 within main body 210 in this example. In practice, PCIe is an interface standard to connect GPU 121 to a motherboard of a computer system. PCIe connector 230 facilitates fast data transfer between GPU 121 and other component(s) of the computer system housing graphics processing subsystem 110. Airflow paths 161-162 that are substantially linear relative to respective axes 131, 141 in FIG. 1 are also shown in FIG. 2B.

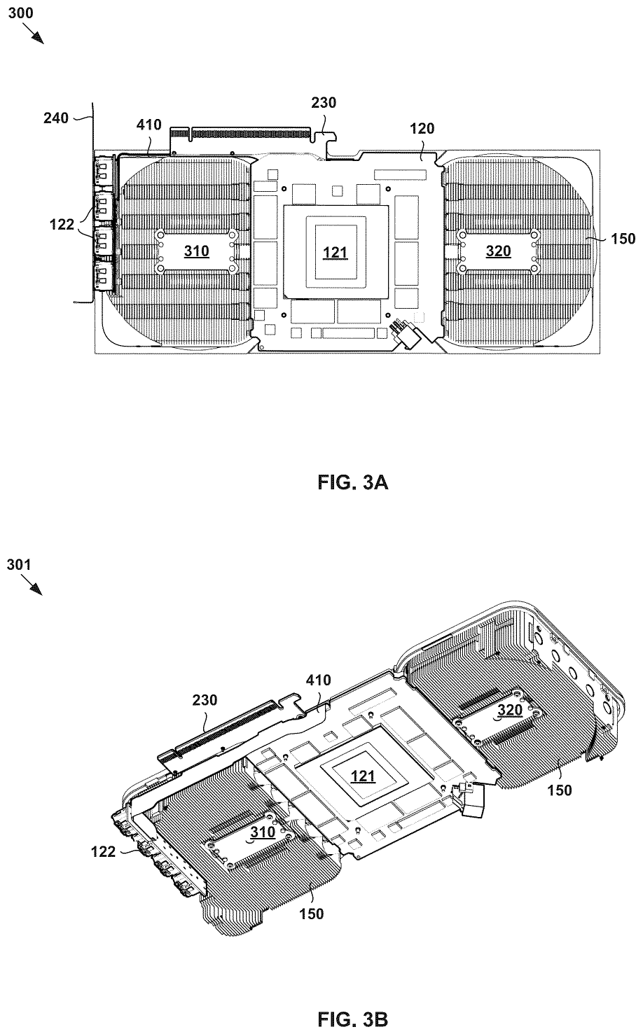

FIG. 3A is a schematic diagram illustrating a top view 300 of a first example graphics processing subsystem 110 in FIG. 1 with its fans 130-140 removed. FIG. 3B is a schematic diagram illustrating a perspective view 301 of a first example graphics processing subsystem 110 in FIG. 1 with its fans 130-140 removed. As shown, I/O port bracket 240 may be a plate (e.g., metal plate) that is designed to hold or secure multiple I/O ports 122 (also shown in FIG. 1). Example I/O ports 122 include high-definition multimedia interface (HDMI), DisplayPort, digital visual interface (DVI), etc. HDMI may be used for connecting a computer to a television or computer monitor. In the example in FIGS. 3A-B, I/O ports 122 may be positioned at one end of graphics processing subsystem 110 that is adjacent to first fan 130.

In practice, HDMI may be used to transmit both high-definition video and audio through a single cable. The DisplayPort may be used for connecting a computer to a monitor. DisplayPort is often used for high-resolution and high-refresh-rate monitors. I/O ports 122 may connect PCB 120 to external device(s), such as monitor, virtual reality (VR) headset, and other peripheral(s). GPU 121 may be configured to process input data to generate output data in a format that is transmittable via I/O ports 122. This may involve converting digital signals into the appropriate format for a connected display (e.g., monitor). In practice, firmware and/or drivers of GPU 121 may be configured to control how data is sent through I/O ports 122.

As shown in FIGS. 3A-B, heat sink 150 may be thermally coupled to, and configured to extract heat from, PCB 120 and/or GPU 121. Heat sink 150 may include any suitable type of heat dissipation or transference mechanism, such as a set of cooling fins, heat pipes, etc. For example, heat sink 150 may include cooling fins to increase surface area to improve heat dissipation. In practice, GPU 121 may be physically attached to heat sink 150 using any suitable material (e.g., thermal pad) to ensure effective heat transfer between GPU 121 and heat sink 150.

During operation, heat sink 150 may absorb and dissipate heat generated by GPU 121. By drawing cool air outside of graphics processing subsystem 110 and pushing the air through fans 130-140, openings 171-172 and heat sink 150, the temperature of GPU 121 may be lowered. This may help GPU 121 to maintain optimal or near-optimal operating temperatures when performing compute-intensive tasks, thereby reducing the risk of overheating. As shown in FIGS. 3A-B, graphics processing subsystem 110 may include any suitable support structures 310-320 (also known as fan pillows) to support the placement of fans 130-140 above heat sink 150.

FIG. 4A is a schematic diagram illustrating a top view 400 of example PCB 120 in a first example graphics processing subsystem 110 in FIG. 1. FIG. 4B is a schematic diagram illustrating a perspective view 401 of example PCB 120 in a first example graphics processing subsystem 110 in FIG. 1. To create opening 171, PCB 210 may be positioned at a distance from I/O ports 122 to create a spatial separation (see 420 in FIG. 4A) between them. This way, PCB 120 may be positioned away from first axis 131 such that first airflow path 161 remains substantially linear relative to first axis 131. This allows both fans 130-140 to be blow-through fans.

PCB 120 may be communicatively coupled with I/O ports 122 via connector 410 that extends along the distance between them. As used herein, the term “connector” may refer generally to any suitable structure(s) or component(s) capable of providing communicative coupling between PCB 120 and I/O ports 122. Connector 410 may be in any suitable shape and size such that airflow paths 161-162 are substantially unimpeded by connector 410. In FIGS. 4A-B, connector 410 may have an elongated shape and extend along the distance between PCB 120 and I/O ports 122, outside of a boundary of first fan 130 (see 610 in FIG. 6A). Spatial separation 420 between PCB 120 and I/O ports 122 should be contrasted against conventional approaches where PCB 120 is directly attached to I/O ports 122 and positioned above first fan 130, which obstructs airflow path 161. To facilitate spatial separation 420, PCB 120 may be configured to occupy a smaller portion of a total width of graphics processing subsystem 110 compared to conventional graphics processing subsystems.

### Positioning of PCB

FIG. 5 which is a schematic diagram illustrating a side view 500 of a second example graphics processing subsystem 510 according to embodiments of the present disclosure. In the first example in FIGS. 1-4B, PCB 120 may be positioned substantially below fans 130, 140 in a middle section of graphics processing subsystem 110 such that airflow paths 161-162 are substantially linear relative to respective fan axes 131, 141. In a second example in FIG. 5, PCB 520 may be positioned substantially above fans 530.

As used herein, the term “substantially below” may refer generally to a lower vertical positioning within graphics processing subsystem 110/510, such as when viewed from its side (e.g., see FIG. 1). The term “substantially above” may refer generally to a higher vertical positioning within graphics processing subsystem 110/510, such as when viewed from its side (e.g., see FIG. 5). Any suitable vertical positioning of PCB 120/520 relative to fans 130/530, 140/540 may be configured according to the desired implementation.

In the example in FIG. 5, graphics processing subsystem 510 may include PCB 520 on which GPU 521 is disposed, blow-through fans 530-540, heat sink 550 and I/O ports 522. Similar to the first example in FIGS. 1-4B, PCB 520 may be placed between fan axes 531, 541 in a middle section of graphics processing subsystem 510. Similarly, PCB 520 may be shaped and positioned such that (a) first airflow path 561 is substantially linear relative to first axis 531 about which first fan 530 rotates, and (b) second airflow path 562 is substantially linear relative to second axis 541 about which second fan 540 rotates.

For first blow-through fan 530, first airflow path 561 may traverse through (a) opening 571 above first fan 530 (e.g., outside of a first edge of PCB 520), (b) first fan 530, (c) opening 572 below first fan 530 and (d) heat sink 550. For second blow-through fan 540, second airflow path 562 may traverse through (a) opening 573 above second fan 540 (e.g., outside of a second edge of PCB 520), (b) second fan 540, (c) opening 574 below second fan 540 and (d) heat sink 550. Note that example PCB 120 in FIGS. 4A-B may be used in graphics processing subsystem 510 in FIG. 5.

### Example PCB with Curved-In Edges

In the embodiments in FIGS. 1-4B, PCB 120 may be configured to have a substantially rectangular or square shape and placed in a middle section of graphics processing subsystem 110 to facilitate a dual blow-through architecture. In this case, PCB 120 may partially overlap with first fan 130 along first axis 131 and second fan 140 along second axis 141. An example is shown in FIG. 6A, which is a schematic diagram illustrating a top view 600 of a first example PCB 120 in graphics processing subsystem 110/510.

In the example in FIG. 6A, PCB 120 may be configured to have a substantially rectangular or square shape with four generally straight edges 630-633, at least two of them having any suitable width=W1 (see 630-631). First fan 130 whose outer perimeter or boundary is indicated at 610 may be configured to have any suitable first diameter=D1. In this case, there may be a partially overlapping area (see 640) between PCB 120 (e.g., portion adjacent to first edge 632) and first fan 130 along first axis 131 (e.g., when viewed in the direction of first axis 131).

Second fan 140 whose outer boundary is indicated at 620 may be configured to have any suitable second diameter=D2 (e.g., D1=D2). In this case, there may be another partially overlapping area (see 641) between PCB 120 (e.g., portion adjacent to second edge 633) and second fan 140 along second axis 141 (e.g., when viewed in the direction of second axis 141). According to the embodiments of the present disclosure, overlapping area 630/631 may be configured to be less than a predetermined threshold such that airflow paths 160-161 remain substantially linear relative to respective fan axes 131, 141. Any suitable threshold may be configured in practice, such as 15 or 25% of fan area, etc.

To further improve airflow and cooling performance, PCB 120 may be shaped such that there is substantially no overlap between PCB 120 and fans 130, 140 along respective axes 131, 141. Here, the term “substantially no overlap” may refer generally to zero overlap, or additionally with minor deviation(s) therefrom. One example is shown in FIG. 6B, which is a schematic diagram illustrating a top view 601 of a second example PCB 120 that is shaped to include curved-in edges. In FIG. 6B, PCB 120 may be configured to have a generally biconcave lens shape, which includes two substantially straight/flat edges 650-651 and two curved-in (i.e., concave) edges 652-653. The widest part of PCB 120 may be configured with width=W1, and its narrowest part with W2<W1.

First curved-in edge 652 adjacent to first fan 130 may be configured with any suitable curvature such that there is substantially no overlap between PCB 120 and first outer boundary 610 of first fan 130 along fan axis 131 (e.g., when viewed in the direction of fan axis 131). Second curved-in edge 653 adjacent to second fan 140 may be configured with any suitable curvature such that there is substantially no overlap between PCB 120 and second outer boundary 620 of second fan 140 along fan axis 141 (e.g., when viewed in the direction of fan axis 141). In practice, PCB 120 in the example in FIG. 6B may be positioned substantially below (similar to FIG. 1) or substantially above (similar to FIG. 5) fans 130, 140. The example in FIG. 6B is suitable for graphics processing subsystems that include higher-performance GPU(s), which require further improved heat dissipation compared to the example in FIG. 6A.

### Example PCB with Cut-Outs

According to embodiments of the present disclosure, a PCB may be shaped to include cut-outs to facilitate a dual blow-through architecture. Some embodiments will be discussed using FIGS. 7A-B and 8A-B. Here, FIG. 7A is a schematic diagram illustrating a top view 700 of a third example PCB 720 that is shaped to include cut-outs. FIG. 7B is a schematic diagram illustrating a side view 701 of a third example graphics processing subsystem 710 that includes PCB 720 shaped with cut-outs 780-781. FIG. 8 is a schematic diagram illustrating a side view 800 of a fourth example graphics processing subsystem 810 that includes PCB 720 shaped with cut-outs 780-781.

Referring first to FIGS. 7A-B, PCB 720 may be generally rectangular with width=W1 and shaped to include two cut-outs 780-781 to create respective openings 771-772. Depending on the desired implementation, one end of PCB 720 that is adjacent to first fan 730 may connect directly with I/O ports 722. In this case, a separate connector (e.g., 410 in FIGS. 4A-B) is not required.

First cut-out 780 in PCB 720 may be shaped (e.g., generally circular) and positioned (e.g., below first fan 730) such that first airflow path 761 traverses through first fan 730 and first cut-out 780 along first axis 731. In the example in FIG. 7A, an area of first cut-out 780 may substantially fully overlap with an area of first fan 730 along first axis 731 (e.g., when viewed in the direction of axis 731). Any suitable size may be configured for first cut-out 780. For example, first cut-out 780 may have diameter=D1 associated with first fan 730, etc.

Similarly, second cut-out 781 in PCB 720 may be shaped (e.g., generally circular) and positioned (e.g., below second fan 740) such that second airflow path 762 traverses through second fan 740 and second cut-out 781 along second axis 741. In the example in FIG. 7A, an area of second cut-out 781 may align and substantially fully overlap with an area of second fan 740 along second axis 741 (e.g., when viewed in the direction of axis 741). Any suitable size may be configured for second cut-out 781, such as diameter=D2 associated with second fan 740, etc. The term “substantially fully overlap” may refer generally to cut-out 780/781 overlapping or intersecting with fan 730/740 completely, or additionally with minor deviation(s). Depending on the desired implementation, cut-out 780/781 may be smaller than the diameter of fan 730/740.

In the example in FIG. 7A, PCB 720 may be positioned substantially below fans 730, 740. Another example graphics processing subsystem 810 is shown in FIG. 8, where PCB 720 is positioned substantially below or above fans 830, 840 similar to FIG. 5. In this case, first cut-out 780 may be shaped to create first opening 871 above first fan 830. During operation, first airflow path 861 for cooling GPU 721 may traverse through (a) first opening 871 provided by first cut-out 780, (b) first fan 830, (c) second opening 872 below first fan 830 and (d) heat sink 850. Similarly, second cut-out 781 may be shaped to create second opening 873 above second fan 830. During operation, second airflow path 862 may traverse through (a) third opening 873 provided by second cut-out 781, (b) second fan 840, (c) fourth opening 874 below second fan 840 and (d) heat sink 850.

### Additional Fans

According to embodiments of the present disclosure, more than N=2 fans may be configured in a graphics processing subsystem. Some embodiments will be discussed below using FIGS. 9A-B. For simplicity, reference numerals 120-172 in FIG. 1 are used. In the following embodiments, it should be understood that PCB 120 in FIGS. 9A-B may be configured to have any suitable shape, various embodiments of which have been discussed above (e.g., see FIGS. 6A-B, 7A) and not repeated here for brevity.

FIG. 9A is a schematic diagram illustrating a fifth example graphics processing subsystem 900 that includes three fans. In the example in FIG. 9A, graphics processing subsystem 900 may include three fans: first fan 130, second fan 140 and third fan 910. First fan 130 and second fan 140 may be configured to be blow-through fans. Third fan 910 may be a non-blow-through fan and positioned substantially above (or below) PCB 120.

FIG. 9B is a schematic diagram illustrating a sixth example graphics processing subsystem 901 that includes four fans: first fan 130, second fan 140, third fan 920 and fourth fan 930. PCB 120 may be shape and positioned such that (a) first airflow path 161 is substantially linear relative to first axis 131 shared by first fan 130 and third fan 920, and (b) second airflow path 162 is substantially linear relative to second axis 141 shared by second fan 140 and fourth fan 930. This way, all four fans 130, 140, 920, 930 may operate as blow-through fans to further improve heat dissipation. Depending on the desired implementation, PCB 120 in FIG. 9B may be positioned substantially below one set of fans (e.g., 130-140) and substantially above another set of fans (e.g., 920-930).

### Computer System

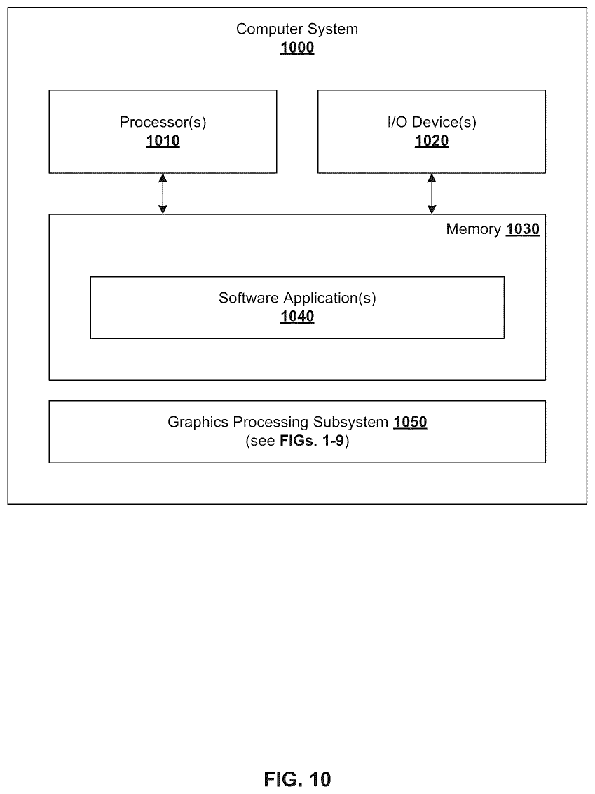

FIG. 10 is a schematic diagram illustrating an example computer system 1000 that includes a graphics processing subsystem according to embodiments of the present disclosure. As shown, computer system 1000 may include graphics processing subsystem 1050 that is configured according to embodiments of the present disclosure. Computer system 1000 may include first processor(s) 1010 and any suitable I/O device(s) 1020. A particular first processor 1010 may be a central processing unit (CPU). Computer system 1000 may include memory 1030 or non-transitory computer-readable medium having stored thereon instructions or program code that, when executed by first processor 1010, cause the processor to implement software application(s) 1040.

Graphics processing subsystem 1050 may include a first fan, a second fan and a PCB on which a second processor (e.g., GPU) is disposed. The first fan may be associated with a first axis about which the first fan is rotatable. The second fan may be associated with a second axis about which the second fan is rotatable. The PCB may be shaped and positioned such that (a) a first airflow path for cooling the processor traverses through the first fan and a first opening below the first fan, and (b) a second airflow path for cooling the processor traverses through the second fan and a second opening below the second fan. The first airflow path and the second airflow path are substantially linear relative to the respective first axis and second axis.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or any combination thereof.

The drawings are only illustrations of an example, wherein the units or procedure shown in the drawings are not necessarily essential for implementing the present disclosure. Those skilled in the art will understand that the units in the device in the examples can be arranged in the device in the examples as described or can be alternatively located in one or more devices different from that in the examples. The units in the examples described can be combined into one module or further divided into a plurality of sub-units.

1. A graphics processing subsystem, comprising:
a first fan that is associated with a first axis about which the first fan is rotatable;
a second fan that is associated with a second axis about which the second fan is rotatable; and
a printed circuit board (PCB) on which a processor is disposed, wherein the PCB is shaped and positioned such that:
a first airflow path for cooling the processor traverses through the first fan and a first opening below the first fan, the first airflow path being substantially linear relative to the first axis; and
a second airflow path for cooling the processor traverses through the second fan and a second opening below the second fan, the second airflow path being substantially linear relative to the second axis.

2. The graphics processing subsystem of claim 1, wherein the PCB is positioned at a distance from multiple input/output (I/O) ports of the graphics processing subsystem, the PCB being communicatively coupled to the multiple I/O ports via a connector.

3. The graphics processing subsystem of claim 2, wherein the multiple I/O ports are positioned adjacent to the first fan, and the connector is configured to have an elongated shape that extends along the distance, outside of a boundary of the first fan.

4. The graphics processing subsystem of claim 1, wherein the PCB is positioned between the first axis and the second axis in a middle section of the graphics processing subsystem such that the first airflow path traverses outside of a first edge of the PCB and the second airflow path traverses outside of a second edge of the PCB.

5. The graphics processing subsystem of claim 1, wherein the PCB is positioned substantially below both the first fan and the second fan to create the first opening below the first fan and the second opening below the second fan.

6. The graphics processing subsystem of claim 1, wherein the PCB is positioned substantially above both the first fan and the second fan.

7. The graphics processing subsystem of claim 1, wherein the PCB is configured to have a generally rectangular or square shape such that the PCB partially overlaps with at least one of: the first fan along the first axis and the second fan along the second axis.

8. The graphics processing subsystem of claim 1, wherein the PCB is shaped to include:
a first curved-in edge such that there is substantially no overlap between the PCB and a first outer boundary of the first fan along the first axis; and
a second curved-in edge such that there is substantially no overlap between the PCB and a second outer boundary of the second fan along the second axis.

9. The graphics processing subsystem of claim 1, wherein the PCB is shaped to include:
a first cut-out such that the first airflow path traverses through the first cut-out before or after the first fan along the first axis; and
a second cut-out such that the second airflow path traverses through the second cut-out before or after the second fan along the second axis.

10. The graphics processing subsystem of claim 1, further comprising a heat sink that is thermally coupled to the processor such that the first airflow path and the second airflow path traverse through the respective first opening and second opening in the heat sink.

11. A computer system, comprising:
a first processor;
a non-transitory computer-readable medium having stored thereon instructions that are executable by the processor; and
a graphics processing subsystem that includes a first fan, a second fan and a printed circuit board (PCB) on which a second processor is disposed, wherein the first fan is associated with a first axis about which the first fan is rotatable, the second fan is associated with a second axis about which the second fan is rotatable, and the PCB is shaped and positioned such that:
a first airflow path for cooling the second processor traverses through the first fan and a first opening below the first fan, the first airflow path being substantially linear relative to the first axis; and
a second airflow path for cooling the second processor traverses through the second fan and a second opening below the second fan, the second airflow path being substantially linear relative to the second axis.

12. The computer system of claim 11, wherein the PCB is positioned at a distance from multiple input/output (I/O) ports of the graphics processing subsystem, the PCB being communicatively coupled to the multiple I/O ports via a connector.

13. The computer system of claim 12, wherein the multiple I/O ports are positioned adjacent to the first fan, and the connector is configured to have an elongated shape that extends along the distance, outside of a boundary of the first fan.

14. The computer system of claim 11, wherein the PCB is positioned between the first axis and the second axis in a middle section of the graphics processing subsystem such that the first airflow path traverses outside of a first edge of the PCB and the second airflow path traverses outside of a second edge of the PCB.

15. The computer system of claim 11, wherein the PCB is positioned substantially below both the first fan and the second fan to create the first opening below the first fan and the second opening below the second fan.

16. The computer system of claim 11, wherein the PCB is positioned substantially above both the first fan and the second fan.

17. The computer system of claim 11, wherein the PCB is configured to have a generally rectangular or square shape such that the PCB partially overlaps with at least one of: the first fan along the first axis and the second fan along the second axis.

18. The computer system of claim 11, wherein the PCB is shaped to include:
a first curved-in edge such that there is substantially no overlap between the PCB and a first outer boundary of the first fan along the first axis; and
a second curved-in edge such that there is substantially no overlap between the PCB and a second outer boundary of the second fan along the second axis.

19. The computer system of claim 11, wherein the PCB is shaped to include:
a first cut-out such that the first airflow path traverses through the first cut-out before or after the first fan along the first axis; and
a second cut-out such that the second airflow path traverses through the second cut-out before or after the second fan along the second axis.

20. The computer system of claim 11, wherein the graphics processing subsystem further comprises a heat sink that is thermally coupled to the second processor such that the first airflow path and the second airflow path traverse through the respective first opening and second opening in the heat sink.
